(19) United States
(12) Patent Application Publication
(10) Pub. No.: US 2025/0091861 A1
(43) Pub. Date: Mar. 20, 2025

(54) LASER MICROMACHINING OF MEMS RESONATORS FROM BULK OPTICALLY TRANSPARENT MATERIAL

(71) Applicant: The Regents of the University of California, Oakland, CA (US)

(72) Inventors: Daryosh VATANPARVAR, Irvine, CA (US); Andrei M. SHKEL, irvine, CA (US); Danmeng WANG, Irvine, CA (US)

(73) Assignee: The Regents of the University of California, Oakland, CA (US)

(21) Appl. No.: 18/727,238

(22) PCT Filed: Jan. 6, 2023
(86) PCT No.: PCT/US2023/060231

§ 371 Date: Jul. 8, 2024

Related U.S. Application Data
(60) Provisional application No. 63/297,610, filed on Jan. 7, 2022.

(51) Int. Cl. B81C 1/00

(52) U.S. Cl. CPC B81C 1/00595; B81C 1/00515; B81C 1/00539

(57) ABSTRACT

Systems, processes and devices are provided for laser-based manufacturing of resonators and MEMS devices from bulk material including optically transparent material. Processes include digital marking of resonator structures in bulk material through non-linear interaction of ultrafast laser beam inscribing and material. The resonator structure may be defined and released through selective wet etching of the laser-modified areas, utilizing a combination of basic and acidic aqueous solutions. Processes can also include hydrofluoric thinning prior to wet etching to prevent laser surface damages. Systems and processes can pattern and fabricate resonator structures and concentricring structures. Embodiments provide miniaturized vibratory sensors from low loss material, such as fused silica and quartz, with an improved resolution and accuracy of measurements for inertial sensing, time referencing, bio-sensing and acoustic sensing.

### CROSS REFERENCE TO RELATED APPLICATION

This application claims priority to U.S. provisional application No. 63/210,595 titled LASER MICROMACHINING OF MEMS RESONATORS FROM BULK OPTICALLY TRANSPARENT MATERIAL filed on Jan. 7, 2022, the content of which is expressly incorporated by reference in its entirety.

### STATEMENT OF GOVERNMENT SUPPORT

This invention was made with Government support under Grant No. N00014-19-1-2338 awarded by the Office of Naval Research and Grant No. N66001-16-1-4021 awarded by Defense Advanced Research Projects Agency (DARPA) and the United States Navy. The Government has certain rights in the invention.

### FIELD

The present disclosure generally relates to processes, systems and device configurations for fabricating MEMS (micro-electromechanical system) devices, and in particular to machining of vibratory MEMS resonators from material including bulk optically transparent material.

### BACKGROUND

Vibratory MEMS are conventionally fabricated through bulk-micromachining of crystalline or amorphous silicon as the structural material. Over the past decades, silicon MEMS resonators have enabled different applications. The accuracy and resolution of today's state-of-the-art silicon vibratory sensors are limited by a relatively large intrinsic energy loss of silicon material. There is a desire for resonators made with improved properties and from other materials.

There is also a desire for processes that allow for other materials to be used. Manufacturing of micro-scale structures is often limited to wet etching and plasma etching techniques. Wet etching does not provide anisotropic etch profiles and lacks etch rate controllability and repeatability, which is needed for precision manufacturing. Plasma etching provides anisotropic etching with adequate control over etch profile. However, plasma etching processes are very complex and include many steps, such as lithography, vapor deposition, electroplating, masking, temporary and permanent wafer bonding. Most importantly, the maximum achievable aspect ratio through plasma etching is limited, typically to below 10:1. In addition, plasma etching produces a large amount of heat, increasing the temperature of materials, causing large thermo-mechanical stress and failure when integrated with other materials with not matching thermal characteristics. There exists a need for new processes, systems and devices for fabrication MEMS devices.

Recently, Femtosecond Laser-Induced Chemical Etching (FLICE) technology was considered as an alternative to plasma etching, reported in D. Vatanparvar, et al., “Digital Manufacturing of Resonance MEMS from a Single-Layer Fused Silica Material,” IEEE International Conference on Micro Electro Mechanical Systems, 2022. However, it was identified that the natural precursors (impurities, fracture surfaces, and silica-based redeposit) on the surfaces of the fused quartz (FQ) material led to laser damage initiation, including surface cracks, subsurface damage, and material redeposition in Suratwala, T., et al. “HF-based etching processes for improving laser damage resistance of fused silica optical surfaces,” Journal of the American Ceramic Society, vol. 94, no. 2, pp. 416-428, 2011. These imperfections affect structural symmetry, thermal resistance, connectivity and conductivity of metallization and result in high energy dissipations. FIG. 7 illustrates a graphical representation of a prior FQ resonator 705 with a zoomed-in view of the top surface laser damage 710. The prior mitigations of top surface damage 710 are heavily dependent on post-processing which typically lack reproducibility and result in modification of structural properties. Results of treatment noticeably widen trenches 715. As a result, the aspect ratio was reduced from 11:1 to only 6:1 due to laser damage. There is a need to preserve wafer surface features and improve aspect ratios of manufacturing processes.

### BRIEF SUMMARY OF THE EMBODIMENTS

Embodiments are directed to systems, processes and device configurations for fabrication of resonators by laser micromachining, such as MEMS (micro-electromechanical system) devices including vibratory MEMS resonators from bulk material. Embodiments provide processes for laser micromachining of MEMS resonators from bulk of optically transparent material including fused silica or fused quartz with ultra-high aspect ratio features.

According to one embodiment, a manufacturing process is provided fabrication of a resonator by laser micromachining. The method includes controlling, by a device, a laser device relative to material to inscribe at least one resonator structure to the material. The method also includes controlling, by the device, etching of the material to form the at least one resonator from the material, wherein the at least one resonator defined and released by wet etching of material inscribed by the laser device.

In one embodiment, the laser device and etching pattern and fabricate a micro-electromechanical system (MEMS) resonator from optically transparent material.

In one embodiment, the laser device is controlled for ultra-fast-laser-induced modification to produce at least one of a micro-scale and nano-scale mechanical vibratory resonator from the material.

In one embodiment, the material is at least one of optically transparent material, fused silica, fused quartz, and quartz.

In one embodiment, controlling the laser device includes focusing the laser device with a high aperture magnification lens to inscribe the at least one resonator structure to include at least one of proof-mass, suspension element, electrode and cavity.

In one embodiment, controlling the laser device includes inscribing the material through raster motion layer-by-layer, wherein the material is inscribed from bottom to top.

In one embodiment, the laser device is linearly polarized during inscribing.

In one embodiment, controlling etching of the material includes wet etching to selectively etch laser-modified material of the material and mechanical agitation of the material.

In one embodiment, the method includes performing at least one of hydrofluoric thing and hydrofluoric erosion after inscribing the material and prior to etching of the material.

In one embodiment, the method includes fabrication of two-dimensional planes in the optically transparent material by stacking and inscribing lines at a plurality of depths of material.

Another embodiment is directed to a system for fabrication of a resonator by laser micromachining. The system includes a laser device and a controller. The controller is coupled to the laser device and configured to control the laser device relative to material to inscribe at least one resonator structure to the material. The controller is configured to control etching of the material to form the at least one resonator from the material, wherein the at least one resonator defined and released by wet etching of material inscribed by the laser device.

Other aspects, features, and techniques will be apparent to one skilled in the relevant art in view of the following detailed description of the embodiments.

### BRIEF DESCRIPTION OF THE DRAWINGS

The application file contains at least one drawing executed in color. Copies of this patent or patent application publication with color drawing(s) will be provided by the Office upon request and payment of the necessary fee.

The features, objects, and advantages of the present disclosure will become more apparent from the detailed description set forth below when taken in conjunction with the drawings in which like reference characters identify correspondingly throughout and wherein:

FIG. 1 illustrates a process for fabrication of a resonator according to one or more embodiments;

FIG. 2 illustrates a system for fabrication of a resonator according to one or more embodiments;

FIGS. 3A-3B graphically illustrate a process for fabrication of a resonator according to one or more embodiments;

FIGS. 4A-4B graphically illustrate fabrication of two-dimensional planes according to one or more embodiments;

FIG. 5 graphically illustrates concentric ring structures according to one or more embodiments;

FIG. 6 depicts experimental results for a device according to one or more embodiments;

FIG. 7 illustrates laser damage of a conventional process according to prior art;

FIG. 8 is a graphical illustration of a process for fabrication of a resonator according to one or more embodiments;

FIG. 9 is a process for fabrication of a resonator according to one or more embodiments;

FIG. 10 is schematic of a ring structure according to one or more embodiments;

FIG. 11 is a graphical image of a ring structure according to one or more embodiments; and

FIG. 12 is a graphical illustration of quality factor according to one or more embodiments.

### DETAILED DESCRIPTION OF THE EXEMPLARY EMBODIMENTS

### Overview and Terminology

Aspects of this disclosure are directed to laser-based manufacturing processes for patterning and fabricating resonators. Embodiments provide processes and system configurations for laser micromachining of MEMS (micro-electromechanical system) resonators from bulk material including fused silica and fused quartz, with ultra-high aspect ratio features. Embodiments also allow for fabrication of vibratory MEMS resonators from optically transparent material. According to embodiments, a process is provided that includes digital marking of the resonator structure in the bulk material through non-linear interaction of ultrafast laser beam and the material. The resonator structure may then be subsequently defined and released through selective wet etching of the laser-modified areas, utilizing a combination of basic and acidic aqueous solutions.

Systems, processes and devices are provided for laser-based manufacturing of resonators and MEMS devices from bulk material including optically transparent material. Processes include digital marking of resonator structures in bulk material through non-linear interaction of ultrafast laser beam inscribing and material. The resonator structure may be defined and released through selective wet etching of the laser-modified areas, utilizing a combination of basic and acidic aqueous solutions. Processes can also include hydrofluoric thinning prior to wet etching to prevent laser surface damages. Systems and processes can pattern and fabricate resonator structures and concentric-ring structures. Embodiments provide miniaturized vibratory sensors from low loss material, such as fused silica and quartz, with an improved resolution and accuracy of measurements for inertial sensing, time referencing, bio-sensing and acoustic sensing.

Embodiments are also directed to improving quality of laser micromachining. System configurations and processes are provided to fabricate miniaturized fused quartz (FQ) vibratory sensors with an enhanced surface quality. Embodiments may us a four-step FLICE-based fabrication process that provides a highly effective solution for surface laser damage. Laser micromachining according to embodiments may be configured to write features using a laser inside bulk FQ material. According to embodiments, inscribing is performed 5 μm under the top surface of the material and without triggering laser surface damages. According to embodiments, a one or more operations may be performed after laser micromachining for a 5% HF (hydrofluoric) erosion to expose openings of the laser-inscribed micro-features for the subsequence resonator definition and release through wet etching. Experimental results are provided demonstrating feasibility of the processed through fabricated devices with over 15:1 aspect ratio and over 1 million quality factor. Experimental results showed a promised alternative to plasma etching techniques for machining micro-sensors from quartz, Pyrex, and other transparent materials.

As used herein, the terms “a” or “an” shall mean one or more than one. The term “plurality” shall mean two or more than two. The term “another” is defined as a second or more.

The terms “including” and/or “having” are open ended (e.g., comprising). The term “or” as used herein is to be interpreted as inclusive or meaning any one or any combination. Therefore, “A, B or C” means “any of the following: A; B; C; A and B; A and C; B and C; A, B and C”. An exception to this definition will occur only when a combination of elements, functions, steps or acts are in some way inherently mutually exclusive.

Reference throughout this document to “one embodiment,” “certain embodiments,” “an embodiment,” or similar term means that a particular feature, structure, or characteristic described in connection with the embodiment is included in at least one embodiment. Thus, the appearances of such phrases in various places throughout this specification are not necessarily all referring to the same embodiment. Furthermore, the particular features, structures, or characteristics may be combined in any suitable manner on one or more embodiments without limitation.

### EXEMPLARY EMBODIMENTS

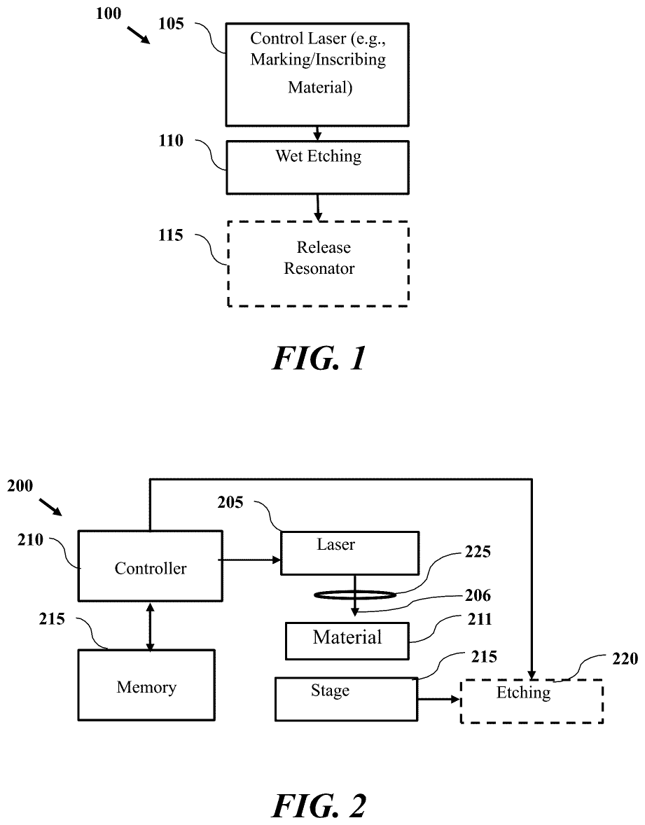

Referring to FIG. 1, a process is illustrated for fabrication of a device, such as MEMS device or resonator, according to one or more embodiments. According to embodiments, process 100 may be a manufacturing process for fabrication of a MEMS resonator, such as miniaturized low-loss resonators, from an optically transparent material. Process 100 may be performed by a system, such as the system described herein with reference to FIG. 2, for the purpose of generating one or more types of resonators. Embodiments described herein may generate resonators used for one or more of inertial sensing, mass sensing, time referencing, bio-sensing, etc.

Process 100 includes controlling a laser device at block 105 to mark a material and wet etching at block 110. At block 105, a device (e.g., controller) may control a laser device relative to an optically transparent material to inscribe resonator structure to the optically transparent material. According to embodiments, a laser device may include one or more laser sources or generators. The laser device, and/or one or more lasers may be controlled to mark and/or inscribe structure such as one or more of an anchor and vibrating element. According to embodiments, at least one portion of an optically transparent material may be marked at block 105. According to other embodiments, at least one region of the optically transparent material may be marked and/or inscribed, such as a first region, a second region, and/or a plurality of additional regions. In one embodiment, the laser device is controlled to inscribe the material through raster motion layer-by-layer from bottom to top. Control of the laser at block 105 can include patterning and fabricating a micro-electromechanical system (MEMS) resonator from optically transparent material.

According to embodiments, process 100 at its core includes two steps of laser marking (e.g., inscribing, patterning) at block 105 and wet etching at block 110. According to embodiments, process 100 does not rely on any prior steps, such as vapor deposition, lithography, wafer bonding, etc. As a result, process 100 and embodiments described herein enable fast prototyping for design optimization and implementation of a wide range of MEMS devices and sensors. Due to the simplicity and flexibility of process 100, laser-based manufacturing according to embodiments becomes attractive to both small companies and larger companies for in-house fabrication of high-performance MEMS sensors.

In one embodiment, the laser is controlled for ultra-fast-laser-induced modification to produce at least one of micro-scale and nan-scale mechanical vibratory resonator from the optically transparent material. Laser patterning with ultrafast lasers sources according to embodiments eliminates temperature gradients outside the focal volume of the laser beam, which is ideal for processing fused silica material next to temperature-sensitive components such as Integrated Circuits (IC) or other MEMS material with high thermal expansion coefficients such as silicon and metals.

Embodiments can include use of ultrafast laser machining processes for desired aspect ratios patterned in fused silica material. Some of the benefits of micromachining micro-resonators with ultra-high aspect ratio features include:
a high aspect-ratio micromachining enables fabrication of micro-resonators with higher inertial mass per a given footprint, which realizes fabrication of smaller resonators without adverse effects on the sensitivity.
a high aspect ratio would also allow us to implement resonator designs that incorporate a large out-of-plane stiffness, reducing the cross-axis coupling and vibration sensitivity of vibratory sensors.

In capacitive resonators fabricated according to embodiments, high aspect ratio electrodes provide high capacitive transduction. Higher capacitive transduction can improve the signal-to-noise ratio in electrostatic detection and reduces the required actuation voltage for driving the resonator. Importantly, high aspect ratio electrodes can enhance the electrostatic frequency tuning capability of the micro-resonator. This property is especially of interest for mode-matching in gyroscope resonators.

According to another embodiment, the laser device is linearly polarized during marking and inscription. For example, the laser device may be controlled to oscillate output in a direction perpendicular to the propagation direction of the laser beam.

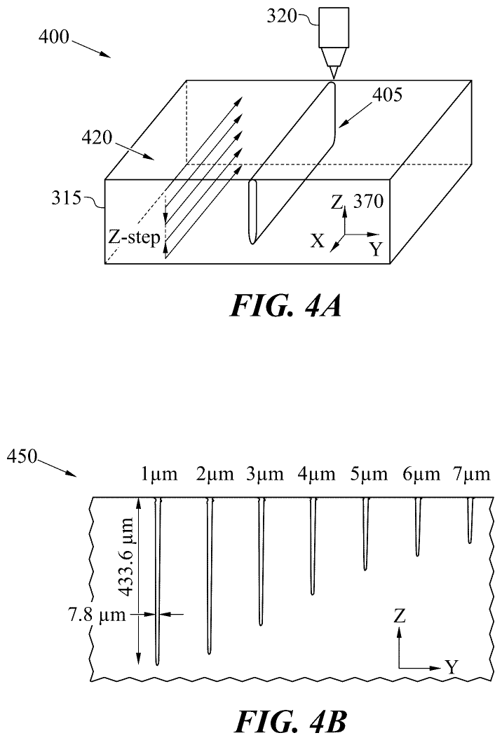

At block 105, multiple resonators or MEMS devices may be marked to an optically transparent material. As described below with reference to FIGS. 4A-4B, two-dimensional (2D) 2D inscription may be performed at block 105. In one embodiment, fabrication of two-dimensional planes in the optically transparent material by stacking and inscribing lines at a plurality of z-steps.

As compared to plasma etching, ultrafast-laser-induced modification at block 105 and wet etching at block 110 allow for defining high-resolution nano to micro-scale features with a virtually unlimited aspect ratio. In the case of capacitive vibratory MEMS, embodiments enable fabrication of resonators with an unprecedented higher capacitive transduction compared to plasma etched fused silica resonators and current silicon-fabricated vibratory sensors. Embodiments provide applications not only for anisotropic etching of 2-dimensional MEMS resonators, but also micromachining stand-alone 3-dimensional MEMS resonators with arbitrary shapes, implementing 3-dimensional designs which are optimized over a specific volume.

Process 100 allows for use on optically transparent material, such as fused silica. At block 105, a laser device may be focused with a high aperture magnification lens to inscribe a resonator structure including at least one of proof-mass, suspension element, electrode and cavity. Fused silica material has an energy loss limit that is two orders of magnitude lower than silicon. A lower intrinsic energy loss, along with other desirable mechanical and optical properties, makes fused silica a desirable material to replace silicon. However, due to the hardness and chemical inertness of the material, precision micromachining of fused silica using conventional techniques is a challenge. Embodiments provide a solution for precision micromachining of fused silica. Embodiments may be applied for micromachining of materials that are optically transparent at the wavelength of the laser beam and exhibit the non-linear laser-material interaction. Materials that fall in this category include but are not limited to fused silica, Pyrex, crystalline quartz, sapphire, etc.

At block 110, process 100 includes controlling etching of the optically transparent material to form a resonator from the material optically transparent material. Block 110 can include controlling etching of the optically transparent material to selectively etch laser-modified material of the optically transparent material. Wet etching in process 100 may include removal or dissolving of material from optically transparent material using one or more of solutions. Wet etching may include immersing the optically transparent material in a liquid etchant solution. According to embodiments, controlling etching of the optically transparent material includes wet etching in combination with mechanical agitation at block 110. According to embodiments, process 100 is a mask-less process, and as such process 100 serves as an easier but much more flexible alternative to plasma etching. Laser-inscribed micro-resonators can be patterned and released deep in the bulk of fused silica material, which provides a self-encapsulation characteristic that is ideal for low-stress vacuum packaging. Co-definition of device layer and handle layer provides a thermo-mechanical stress-free structure that can operate in harsh environments.

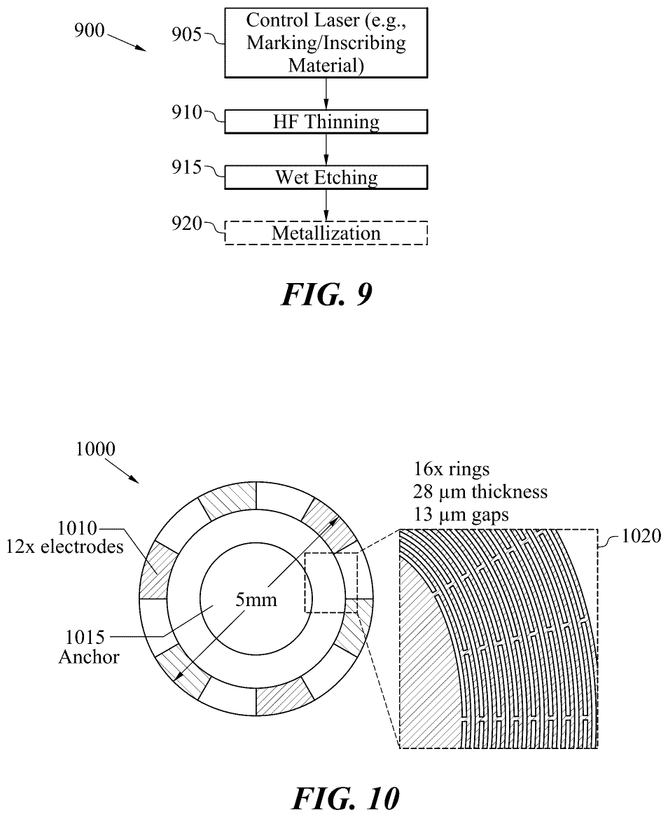

Process 100 may optionally include release of a resonator at block 115. According to embodiments, a resonator structure may be released from the optically transparent material at block 115. Process 100 provides operations for laser micromachining of bulk material to inscribe one or more resonator structures in the material. As discussed herein with reference to FIGS. 8 and 9, laser micromachining may include an operation for hydrofluoric (HF) thinning after laser micromachining and prior to wet etching to remove defects to material from laser inscribing.

FIG. 2 illustrates a system for fabrication of a resonator according to one or more embodiments. According to embodiments, system 200 includes laser device 205 and controller 210. Controller 210 is coupled to laser device 205 and configured to control laser device 205 relative to an optically transparent material to inscribe a resonator structure to the optically transparent material.

According to embodiments, system 200 may include memory 215. Controller 210 may relate to a processor or control device configured to execute one or more operations stored in memory 215. System 200 may perform one or more operations including process 100 of FIG. 1, and process 900 of FIG. 9.

According to embodiments, system 200 may include lens 225 to focus output 206 of laser device 205. Lens 225 may be high aperture magnification lens. System 200 and controller 210 are configured for use on optically transparent material, such as fused silica, shown as material 211. Laser device 205 may be focused with lens 225 to inscribe a resonator structure including at least one of proof-mass, suspension element, electrode and cavity.

According to embodiments, laser device 205 may be configured to provide ultrafast-laser-induced modification to material 211. According to embodiments, laser device 205 may be controlled by controller 201 for ultrafast-laser irradiation of optically transparent material, such as fused silica, with a fluence below the ablation threshold, to interact with the material in a non-linear fashion and locally enhance the selectivity of the material in wet etching processes. In one embodiment, the method further includes fabrication of two-dimensional planes in the optically transparent material by stacking and inscribing lines at a plurality of z-steps.

In certain embodiments, system 200 may include stage 215 configured to retain and/or position material 211. Controller 210 may be configured to control laser device 205 for fabrication of two-dimensional planes in the optically transparent material by stacking and inscribing lines at a plurality of z-steps.

Controller 210 may also be configured to control etching, shown as etching 220, of the optically transparent material 211 to form at least one MEMS device, such as a resonator, from the material optically transparent material 211. Stage 215 may be used for etching of material 211. In certain embodiments, system 200 wet etches material 211 in etching module 220. Stage 215 and etching module 220 may be controlled by controller 200. Operations of system 200 are not limited to optically transparent material and may be applied to bulk material for forming resonator devices.

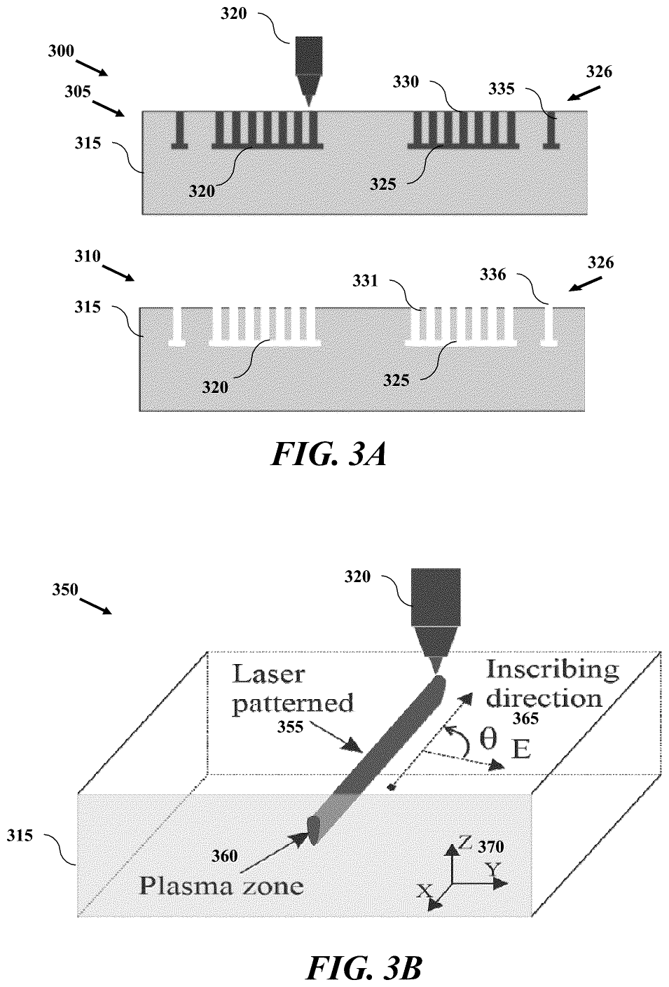

FIGS. 3A-3B graphically illustrate process 300 for fabrication of a resonator according to one or more embodiments. One or more operations of process 300 may include operations of process 100 of FIG. 1. Process 300 includes controlling a laser device 320 to mark material 315, with laser marking shown as 305 and wet etching shown as 310. According to embodiments, process 300 includes ultrafast-laser irradiation at 305 with material 315 being an optically transparent material, such as fused silica. According to embodiments, as described herein, and as shown in 305, embodiments can include utilizing ultrafast-laser-induced modification to produce micro-scale (and nano-scale) mechanical vibratory resonators with optically transparent material as the structural material. Although processes are described with reference to fused silica, it should also be appreciated that the principles and processes described herein can be applied to other transparent materials, which exhibit a similar non-linear interaction with ultrafast laser beams.

According to embodiments, laser marking at 305 is performed with a fluence below the ablation threshold, such that the laser output interacts with the material in a non-linear fashion and locally enhances the selectivity of the material in wet etching processes. According to embodiments, control of the laser may be a type-II modification. Laser marking at 305 may include tightly focusing the ultrafast laser in the bulk of fused silica. Process 300 may include using a high numerical aperture magnification lens to inscribe the resonator structure, including resonator structure the proof-masses, suspension elements, electrodes, and cavity.

Process 300 illustrates material 315 including marking for a first resonator 320 and a second resonator 325 in material 315. Each resonator may include structural elements, such as channels 330 and element 335. In addition, each resonator may be associated with a region or portion of material 315, such as region 326.

According to another embodiment, process 300 may mark a single resonator in material 315, such that first resonator 320 and second resonator 325 make up a single resonator structure. As such, markings in FIG. 3A may relate to a cross-sectional view of a ring resonator.

According to embodiments, laser marking includes inscribing material 315 through a raster motion which is executed layer-by-layer from bottom to top. According to another embodiment, a bottom-to-top laser marking is performed to avoid beam distortions due to material modification in the previous layers. Process 300 may include controlling relative motion of material 315 as a working sample with respect to the laser beam output of laser device 320, along XYZ cartesian axes shown as 370 in material 315. Motion of the material may be achieved through the integration of motorized motion stages and galvanometer mirrors for fast and accurate patterning. According to embodiments, the laser beam output of laser device 320 is linearly polarized during inscription, and the polarization is mechanically or electrically controlled and maintained perpendicular to the direction of laser marking to achieve the highest selectivity of etching. According to certain embodiments, for designs that require a fast change of polarization, circular polarization may be utilized. Process 300 may include control of laser motion planning to minimize structural asymmetries, which may be caused by laser beam anisotropy, pulse energy variations, and marking speed variations throughout the process. Laser-modification of material 315 can precisely mark a resonator. FIG. 3B illustrates laser patterning 350 by laser device 320 according embodiments. Laser patterning may be performed by laser device 320 to material 315. FIG. 3B illustrates laser patterned portion 355 and plasma zone 360. According to embodiments, inscribing direction 365 is controlled. Process 300 may include fabrication of 2-D planes using the ultrafast-laser-induced modification and chemical etching process. FIG. 3B illustrates reference 370 describing two planes (X-axis, Y-axis) for laser marking. As described with reference to FIG. 4A-4B, laser patterns may be in one or more vertical or Z-axis directions.

According to another embodiment, process 300 includes wet etching of material 315 at 310. By way of example, the marked resonator structure may be submerged in a combination of aqueous basic and acidic solutions to selectively etch. Process 300 illustrates material 315 including a first resonator 320 and a second resonator 325 etched in material 315 at 310. Etched structural elements are shown as channels 331 and element 336. Selective etching by process 300 can include etching one or more regions of material 315, such as region 326 associated resonator 325. Etching may precisely define and release the resonator. According to embodiments, process 300 includes selection of type, concentration, and temperature of solutions to provide a fast etch rate while maintaining a high selectivity (typically above 1000:1).

According to embodiments, wet etching at 310 in process 300 is performed along with mechanical agitation to avoid a diffusion-limited etch, which ensures a uniform etch rate across the structure. After wet etching at 310, assuming a release-cavity is patterned, the resonator is released and is free to vibrate. At this point, different motion actuation and detection schemes can be implemented with the fabricated fused silica resonator, such as electrostatic actuation and detection, piezoelectric actuation, piezoresistive detection, optical actuation and detection, etc.

Process 300, and manufacturing processes described herein, can be used for patterning ultra-high aspect ratio low loss fused silica resonators, in which a fused silica device layer is integrated with other types of material as the handle layer, such as silicon or acoustically decoupled photonic crystals.

FIGS. 4A-4B graphically illustrate fabrication of two-dimensional planes according to one or more embodiments. FIG. 4A illustrates laser patterning 405 by laser device 320 to material 315. FIG. 4A illustrates reference 370 describing two planes (X-axis, Y-axis) for laser marking. As described herein, laser patterns may be in one or more vertical or Z-axis directions.

According to embodiments, process 400 for control of laser device 320 includes stacked and inscribed lines at different Z-positions 420. FIG. 4B illustrates marked the lines with large overlaps, corresponding to a z-step size of 1 micron as 450. Results of testing demonstrate laser-modified and wet etched features with aspect ratios as high as 55.6:1 and near-vertical sidewalls.

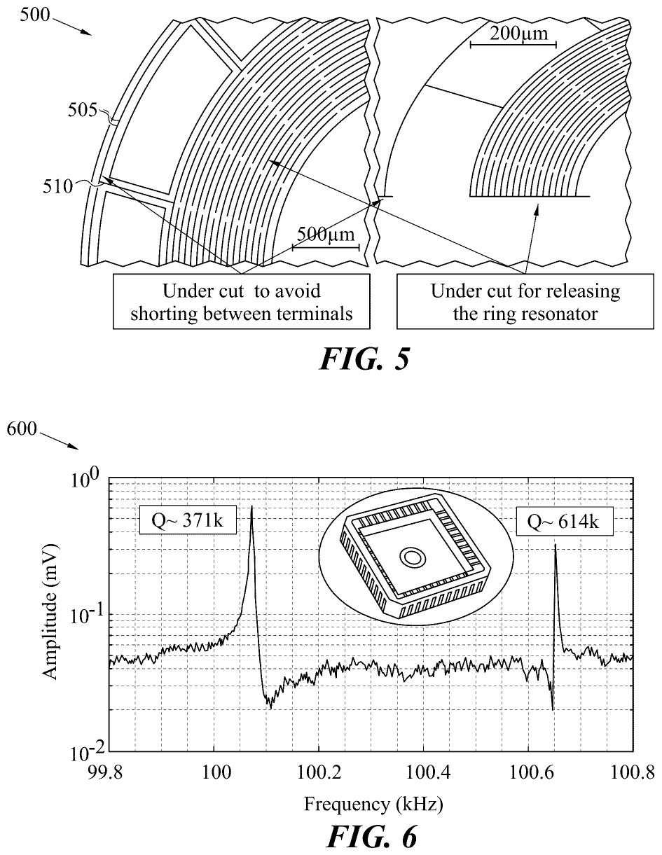

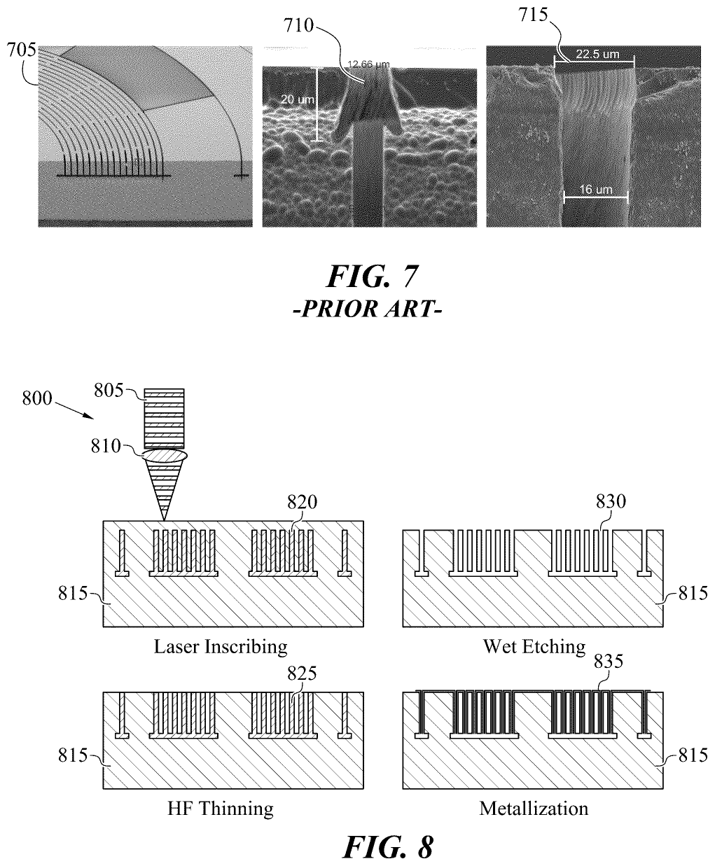

FIG. 5 graphically illustrates concentric ring structures according to one or more embodiments. To demonstrate the feasibility of processes for fabrication of fused silica micro-resonators, experimental ring structures were fabricated including a 25 mm² concentric-ring structure using the described process. FIG. 5 illustrates a portion of a ring structure 500.

To demonstrate the feasibility of the process for fabrication of fused silica micro-resonators, experiments included fabricating a 25 mm² concentric-ring structure. The concentric ring structure and the corresponding release cavity were inscribed in fused silica with an ultrafast laser machine. Laser marking was followed by wet etching in potassium hydroxide (KOH) solution. Optical and SEM images were utilized to make sure the resonator was fully released, illustrated in the included figures. In the prototype, a stand-alone capacitive resonator structure was demonstrated, which included the micro-resonator, electrodes, and the cavity needed for release. Fabrication and release of the concentric ring structure were also demonstrated, with a device-layer thickness of 113 μm and gap size of 9.6 μm (11.8:1 AR).

FIG. 6 depicts experimental results for a device according to one or more embodiments. To demonstrate the functionality of the device through electrostatic actuation and detection, experiments included using a coated the ring structure with thin-film chromium and gold layers. The frequency response of the ring resonator was measured in a 30 μtorr vacuum, with frequency response mapped as 600. The results revealed a frequency split on the order 580 Hz and a quality factor as high as 614 k. Notably, the measured quality factor was 5-times higher than the quality factor reported for a conventional plasma etched ring structure. Results in FIG. 6 are preliminary results.

FIG. 8 is a graphical illustration of a process for fabrication of a resonator according to one or more embodiments. Process 800 may be employed for fabrication of a resonator according to one or more embodiments. One or more operations of process 800 may include operations of process 100 of FIG. 1 and process 900 of FIG. 9. Process 800 includes controlling a laser device 805 to mark material 815, with laser marking shown as 820, HF (hydrofluoric)) thinning at 825 and wet etching shown as 830. Process 800 may optionally include metallization at 835.

According to embodiments, process 800 includes ultrafast-laser irradiation with material 815 being an optically transparent material, such as fused silica, or a bulk material such as fused quartz. According to embodiments, and as described herein, and as shown in 305, embodiments can include utilizing ultrafast-laser-induced modification to produce micro-scale (and nano-scale) mechanical vibratory resonators with optically transparent material as the structural material.

According to embodiments, process 800 includes a FLICE-based process for fabrication of FQ micro-structures to eliminate laser surface damage and material redeposition. Process 800 provides a solution for surface quality enhancement that is highly effective.

According to embodiments, laser micromachining in process 800 may be performed inside bulk material, from bottom to 5 μm under the top surface for laser marking 820. Process 800 uses an ultrafast-laser to interact with FQ with a fluence below the ablation threshold and locally enhance the selectivity of the material in wet etching processes, referred to as type-II modification and reported in: V. Stankevic and G. Raciukaitis, “Formation of rectangular channels in fused silica by laser-induced chemical etching.” Lithuanian Journal of Physics 54, no. 3, 2014. Instead of finishing the laser irradiation on the top surface, compared with other similar implementations, such as D. Vatanparvar, et al., “Digital Manufacturing of Resonance MEMS from a Single-Layer Fused Silica Material,” IEEE International Conference on Micro Electro Mechanical Systems, 2022 and Zhao, Tao, et al., “Fused Silica Gyroscope Resonator Manufactured with Femtosecond Laser Assisted Wet Etching,” IEEE Journal of Microelectromechanical Systems, vol. 31, no. 3, 2022, process 800 completes laser inscribing of the writing patterns under the top surface.

According to embodiments, surfaces of the material may be prepared after laser micromachining. Process 800 may perform HF etching, which may be a form of wet etching that uses hydrofluoric acid to etch out surfaces rather than using a dry plasma process. According to embodiments, openings in the material of the laser-inscribed micro-features may be etched of HF thinned by using 5% HF erosion. HF thinning at 825 can preserve smoothness of the wafer surface and providing access to inscribed features. With HF thinning at 825, process 800 can effectively eliminate laser-induced surface damage and prevent the material redeposition. Process 800 can complete the resonator with the “release” of structures using wet etching at 830, such as KOH etching, which may have over 855:1 selectivity between laser-inscribed and not-inscribed portions of the material. Process 800 may optionally include metal-coating of FQ resonators at 835. Metallization at 835 may be performed for capacitive actuation and detection. Metallization at 835 may be performed by confocal sputter coating or physical vapor deposition using thin layers of platinum, chromium, gold, etc.

FIG. 9 is a process for fabrication of a resonator according to one or more embodiments. Process 900 may be performed to fabricate miniaturized FQ vibratory sensors with an enhanced surface quality. Process 900 may also provide a solution for surface laser damage. Process 9000 may be a fabrication process that includes controlling a laser device for laser inscribing in bulk material, such as fused quartz at block 905. Control of the laser at block 905 may write and/or inscribe a resonator from bottom to top surface of the FQ material. Process 900 writes with laser the features inside bulk of the FQ material at block 905, 5 μm under the top surface, without triggering laser surface damages, At block 910, HF thinning may be performed to eliminate laser-induced surface damage. HF thinning at block 910 follows laser inscribing by a step of 5% HF erosion to expose openings of the laser-inscribed micro-features for the subsequence resonator definition and release through wet etching. At block 915, wet etching may be performed on the inscribed material, such as an aqueous KOH etching, to selectively remove the modified material and release the resonator before metallization. Metallization at block 920 may be optional.

Process 900 and embodiments enable miniaturized vibratory sensors from low loss material, such as fused silica or fused quartz, with an improved resolution and accuracy of measurements for inertial sensing, time referencing, bio-sensing and acoustic sensing, etc. The disclosure includes results of a feasibility study of the process through fabricated prototypes and preliminary characterization results.

Compared to plasma etching, ultrafast-laser-induced modification/inscribing and wet etching of processes described herein allow for high-resolution nano to micro-scale features with a virtually unlimited aspect ratio. Embodiments enable fabrication of MEMS resonators from fused quartz, Pyrex, and other transparent materials with an unprecedentedly higher aspect ratio as compared to more conventional plasma-etched techniques. In addition, embodiments offer advantages in capacitive actuation and detection of resonant structures as compared to plasma-etched and silicon-based fabrication techniques.

Process 900 may include four steps: laser patterning, HF erosion, wet etching, and metal coating (optional) on a single piece of fused quartz material. Process 900 does not rely on any prior steps, such as vapor deposition, lithography, wafer bonding, etc. Compared to other similar laser patterning implementations, process 900 utilizes HF erosion to eliminate laser surface damage and prevent material redeposition without relying on complex post-processing technologies.

Laser patterning with ultrafast laser sources according to embodiments, avoids temperature gradients outside the focal volume of the laser beam and contaminations caused by pre-and post-processing steps, which is ideal for processing fused quartz material next to temperature-sensitive components such as Integrated Circuits (IC) or other MEMS material with high thermal expansion coefficients such as silicon and metals.

Embodiments may be inherently mask-less processes, and thus serves as an easier but much more flexible alternative to plasma etching. Laser-inscribed micro-resonators can be fabricated and released deep in the bulk of fused quartz material, which provides a self-encapsulation characteristic that is ideal for low-stress vacuum packaging. Lastly, the co-definition of device layer and handle layer provides a thermo-mechanical stress-free structure that can operate in harsh environments.

FIG. 10 is schematic of a ring structure according to one or more embodiments. To demonstrate feasibility of processes described herein, experimental results are discussed for ring structure 1000. Ring structure 1000 represents an experimental 25 mm² concentric ring structure resonator fabricated according to embodiments. The concentric rings 1020 were connected to each other in-series through spokes with 30-degrees angle separation. Ring structure 1000 include electrodes 1010 and anchor 1015. An enlarged representation, based on SEM images of the fabricated resonator with a close-up view in FIG. 11, is shown. Experimental results revealed a 15.7:1 aspect ratio with a device-layer thickness of 205 μm and gap size of 13 μm, demonstrating the elimination of surface cracks with a near-vertical etching profile. In the experiment, the speed of laser-writing was limited to 5 mm/sec, with a potential to increase to 20 mm/sec and even to 200 mm/sec. According to embodiments, increased speed of writing will reduce the time of manufacturing by 3×, as compared to plasma etching

FIG. 11 is a graphical image of a ring structure according to one or more embodiments. FIG. 11 shows scanning electron microscope (SEM) images of a resonator 1100. A portion of resonator 1100 is enlarged and shown as 1110 including gap 1115 with a size of 13 μm.

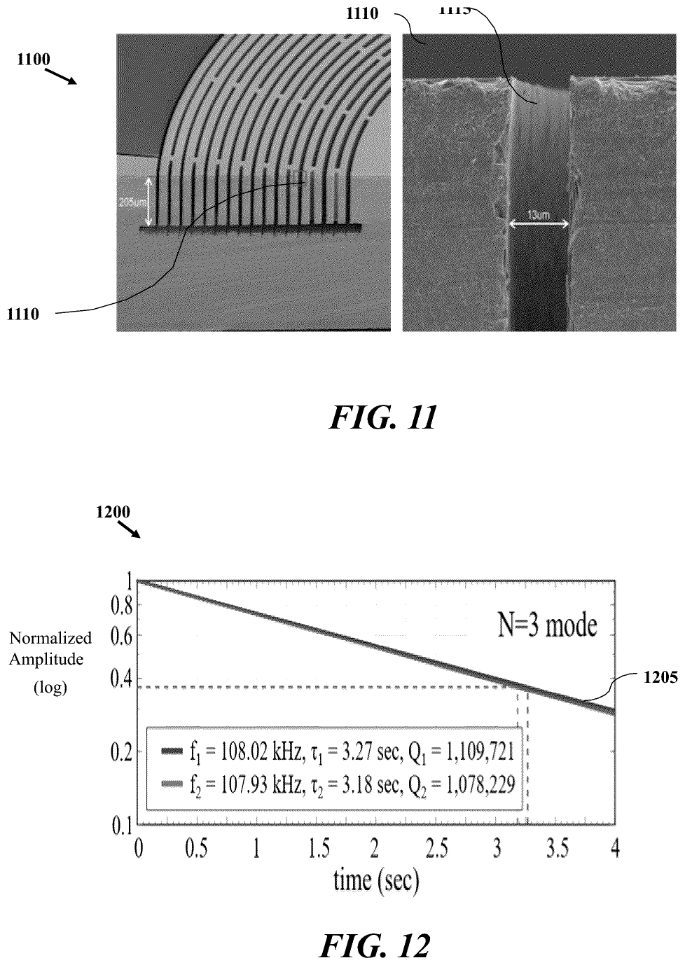

FIG. 12 is a graphical illustration of quality factor according to one or more embodiments. Experimental results include electrostatic characterization of quality factor 1200 of an experimental resonator. An experimental resonator was sputter coated with a 5/10 nm Cr/Au layer. The quality factors of both the x-and y-axis of the operational mode were measured as high as 1.1 million in 0.2 mtorr vacuum. The measurements 1205 are shown in FIG. 12. Notably, metal-coating as one of the energy dissipation sources will reduce quality factor of resonators. It has been demonstrated that with metal coating as thin as 2 nm on the surface of a fused quartz resonator, the mechanical quality factor of the resonator will be reduced by 5 times due to surface loss and mismatch of coefficient of thermal expansion between different materials, which was reported in T. Nagourney, et al. “Effect of metal annealing on the Q-factor of metal-coated fused silica micro shell resonators.” 2015 IEEE International Symposium on Inertial Sensors and Systems (ISISS), 2015. Therefore, the un-coated quality factor of the demonstrated resonator can be presumed to be much higher.

While this disclosure has been particularly shown and described with references to exemplary embodiments thereof, it will be understood by those skilled in the art that various changes in form and details may be made therein without departing from the scope of the claimed embodiments.

What is claimed is:

1. A method for fabrication of a resonator by laser micromachining, the method comprising:
controlling, by a device, a laser device relative to material to inscribe at least one resonator structure to the material; and
controlling, by the device, etching of the material to form the at least one resonator from the material, wherein the at least one resonator defined and released by wet etching of material inscribed by the laser device.

2. The method of claim 1, wherein the laser device and etching pattern and fabricate a micro-electromechanical system (MEMS) resonator from optically transparent material.

3. The method of claim 1, wherein the laser device is controlled for ultra-fast-laser-induced modification to produce at least one of a micro-scale and nano-scale mechanical vibratory resonator from the material.

4. The method of claim 1, wherein the material is at least one of optically transparent material, fused silica, fused quartz, and quartz.

5. The method of claim 1, wherein controlling the laser device includes focusing the laser device with a high aperture magnification lens to inscribe the at least one resonator structure to include at least one of proof-mass, suspension element, electrode and cavity.

6. The method of claim 1, wherein controlling the laser device includes inscribing the material through raster motion layer-by-layer, wherein the material is inscribed from bottom to top.

7. The method of claim 1, wherein the laser device is linearly polarized during inscribing.

8. The method of claim 1, wherein controlling etching of the material includes wet etching to selectively etch laser-modified material of the material and mechanical agitation of the material.

9. The method of claim 1, further comprising performing at least one of hydrofluoric thing and hydrofluoric erosion after inscribing the material and prior to etching of the material.

10. The method of claim 1, further comprising fabrication of two-dimensional planes in the optically transparent material by stacking and inscribing lines at a plurality of depths of material.

11. A system for fabrication of a resonator by laser micromachining, the system comprising:
a laser device; and
a controller, the controller coupled to the laser device and configured to control the laser device relative to material to inscribe at least one resonator structure to the material; and
control etching of the material to form the at least one resonator from the material, wherein the at least one resonator defined and released by wet etching of material inscribed by the laser device.

12. The system of claim 11, wherein the laser device and etching pattern and fabricate a micro-electromechanical system (MEMS) resonator from optically transparent material.

13. The system of claim 11, wherein the laser device is controlled for ultra-fast-laser-induced modification to produce at least one of a micro-scale and nano-scale mechanical vibratory resonator from the material.

14. The system of claim 11, wherein the material is at least one of optically transparent material, fused silica, fused quartz, and quartz.

15. The system of claim 11, wherein controlling the laser device includes focusing the laser device with a high aperture magnification lens to inscribe the at least one resonator structure to include at least one of proof-mass, suspension element, electrode and cavity.

16. The system of claim 11, wherein controlling the laser device includes inscribing the material through raster motion layer-by-layer, wherein the material is inscribed from bottom to top.

17. The system of claim 11, wherein the laser device is linearly polarized during inscribing.

18. The system of claim 11, wherein controlling etching of the material includes wet etching to selectively etch laser-modified material of the material and mechanical agitation of the material.

19. The system of claim 11, further comprising performing at least one of hydrofluoric thing and hydrofluoric erosion after inscribing the material and prior to etching of the material.

20. The system of claim 11, further comprising fabrication of two-dimensional planes in the optically transparent material by stacking and inscribing lines at a plurality of depths of material.
